(19) United States
(12) Patent Application Publication
(10) Pub. No.: US 2021/0065025 A1
(43) Pub. Date: Mar. 4, 2021

(54) MACHINE LEARNING DEVICE, RECEIVING DEVICE AND MACHINE LEARNING METHOD

(71) Applicant: FANUC CORPORATION, Minamitsuru-gun (JP)

(72) Inventors: Kenichiro KURIHARA, Yamanashi (JP); Shinji AKIMOTO, Yamanashi (JP); Motoyoshi MIYACHI, Yamanashi (JP)

(21) Appl. No.: 16/991,285

(22) Filed: Aug. 12, 2020

(30) Foreign Application Priority Data
Sep. 3, 2019 (JP) 2019-160413

(51) Int. Cl. G06N 5/04; H04B 3/04; H04L 1/00; G06N 20/00

(52) U.S. Cl. CPC G06N 5/04; H04B 3/04; H04L 1/0061; G06N 20/00; H04L 1/0052

(57) ABSTRACT

To enable adjustment of digital filters suited to disturbances occurring in the surroundings. A receiving device includes: a digital filter that eliminates or attenuates a disturbance included in a signal received through a communication line; a coefficient adjusting unit that adjusts a coefficient of the digital filter based on operation schedule information of a device causing the disturbance in the communication line; and an information table that records a combination of operation information included in the operation schedule information and a coefficient of the digital filter corresponding to the operation information or correction information of the coefficient, in which the coefficient adjusting unit calculates the coefficient of the digital filter or the correction information of the coefficient from the information table based on the operation information included in the operation schedule information, and adjusts the coefficient of the digital filter.

This application is based on and claims the benefit of priority from Japanese Patent Application No. 2019-160413, filed on 3 Sep. 2019, the content of which is incorporated herein by reference.

### BACKGROUND OF THE INVENTION

### Field of the Invention

The present invention relates to a machine learning device that performs machine learning so that adjustment of a digital filter suited to disturbance occurring in the surroundings can be performed, a receiving device, and a machine learning method.

### Related Art

In a factory environment, communication failure may occur due to disturbance caused by a device such as a motor or an electromechanical device. To eliminate the influence of disturbances including such disturbance, an analog filter or digital filter is used in a receiving circuit in communication.

Japanese Unexamined Patent Application, Publication No. H11-122311 describes a digital wireless communication device that adaptively compensates the characteristics of an analog filter with a digital filter, and selects the compensation characteristics, and further enables proactive control of the compensation characteristics. More specifically, Japanese Unexamined Patent Application, Publication No. H11-122311 describes a digital wireless communication device, the digital wireless communication device including a receiving unit for receiving and demodulating a digital modulation wave. The receiving unit includes an analog filter in a previous stage and a digital filter that allows the filter characteristics to be varied by tap coefficients to compensate for the characteristics of the analog filter. Here, the test signal generating unit supplies a test signal TS to the receiving unit. The error state detecting unit detects a predetermined error state ER based on the digital demodulated signal RS of the test signal by the receiving unit. Furthermore, based on the detected error state, the tap coefficient setting unit provisionally sets tap coefficients sequentially in order of decreasing error state, repeats the abovementioned test processing, and finally sets tap coefficients for minimizing the error state.

Patent Document 1: Japanese Unexamined Patent Application, Publication No. H11-122311

### SUMMARY OF THE INVENTION

Compared to analog filters, the adjustment of digital filters is relatively easy, and it is desired to adjust digital filters suited to the disturbance occurring in the surroundings.

According to the first aspect of the present disclosure, a receiving device includes: a digital filter that eliminates or attenuates a disturbance included in a signal received through a communication line; a coefficient adjusting unit that adjusts a coefficient of the digital filter based on operation schedule information of a device causing the disturbance in the communication line; and an information table that records a combination of operation information included in the operation schedule information and a coefficient of the digital filter corresponding to the operation information or correction information of the coefficient, in which the coefficient adjusting unit calculates the coefficient of the digital filter or the correction information of the coefficient from the information table based on the operation information included in the operation schedule information, and adjusts the coefficient of the digital filter.

According to the second aspect of the present disclosure, a machine learning device (200) that performs machine learning for an optimal coefficient of a digital filter relative to a receiving device which includes: the digital filter that eliminates or attenuates a disturbance included in a signal received through a communication line; a coefficient adjusting unit that adjusts a coefficient of the digital filter based on operation schedule information of a device causing the disturbance in the communication line; an information table that records a combination of operation information included in the operation schedule information and a coefficient of the digital filter corresponding to the operation information or correction information of the coefficient; and a communication error detecting unit that detects a communication error based on an output of the digital filter, includes: a state acquiring unit that acquires operation information of the device causing the disturbance in the communication line and the coefficient of the digital filter, as state information; an action information outputting unit that outputs action information including adjustment information of the coefficient included in the state information to the coefficient adjusting unit; a determination information acquiring unit that acquires determination information indicating a status of a communication error from the communication error detecting unit; and a reward calculating unit that gives a reward relative to a variation in the communication error based on the determination information, in which the machine learning device performs machine learning for an optimal coefficient of the digital filter so that the communication error decreases, using a value of the reward.

According to the third aspect of the present disclosure, a receiving device includes: the machine learning device according to the first aspect, and a receiving device including: a digital filter that eliminates or attenuates a disturbance included in a signal received through a communication line; a coefficient adjusting unit that adjusts a coefficient of the digital filter; a communication error detecting unit that detects a communication error based on an output of the digital filter; and an information table that indicates operation information of a device causing the disturbance in the communication line and the coefficient that is optimized or adjustment information of the coefficient outputted from the machine learning device.

According to the fourth aspect of the present disclosure, a machine learning method of a machine learning device that performs machine learning for an optimal coefficient of a digital filter relative to a receiving device which includes: a digital filter that eliminates or attenuates a disturbance included in a signal received through a communication line; a coefficient adjusting unit that adjusts a coefficient of the digital filter based on operation schedule information of a device causing the disturbance in the communication line; an information table that records a combination of operation information included in the operation schedule information and a coefficient of the digital filter corresponding to the operation information or correction information of the coefficient, and a communication error detecting unit that detects a communication error based on an output of the digital filter, the machine learning method comprising the steps of: acquiring operation information of the device causing the disturbance in the communication line and the coefficient of the digital filter as state information; outputting action information including adjustment information of the coefficient included in the state information to the coefficient adjusting unit; acquiring determination information indicating a status of a communication error from the communication error detecting unit; giving a reward in relation to a variation in the communication error based on the determination information; and performing machine learning for an optimal coefficient of the digital filter so that the communication error decreases, using a value of the reward.

According to aspects of the present disclosure, it is possible to adjust a digital filter suited to the disturbance occurring in the surroundings.

### BRIEF DESCRIPTION OF THE DRAWINGS

FIG. 1 is a block diagram showing the configuration after machine learning of a receiving device according to a first embodiment of the present disclosure;

FIG. 2 is a block diagram showing the configuration during machine learning of the receiving device according to the first embodiment of the present disclosure;

FIG. 3 is a block diagram showing a configuration example of a FIR digital filter;

FIG. 4 is an explanatory diagram showing a state in which digital filters having different coefficients are set according to a machining type of a machine serving as a machine tool;

FIG. 5 is a diagram showing the types of machining in a case in which two machines serving as machine tools are arranged side by side;

FIG. 6 is a block diagram showing a configuration of a machine learning unit 200 of the present disclosure;

FIG. 7 is a flowchart for explaining the operation of the machine learning unit 200 according to a second configuration example of the present disclosure; and

FIG. 8 is a block diagram showing another configuration example of a receiving device including a receiving unit and a machine learning device.

### DETAILED DESCRIPTION OF THE INVENTION

Hereinafter, embodiments of the present disclosure will be described in detail with reference to the accompanying drawings.

### First Embodiment

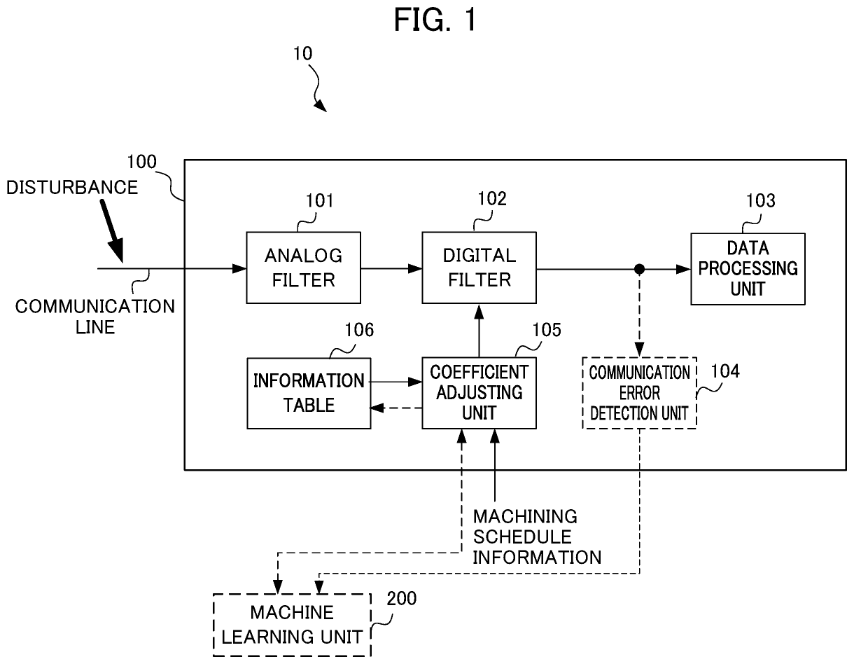

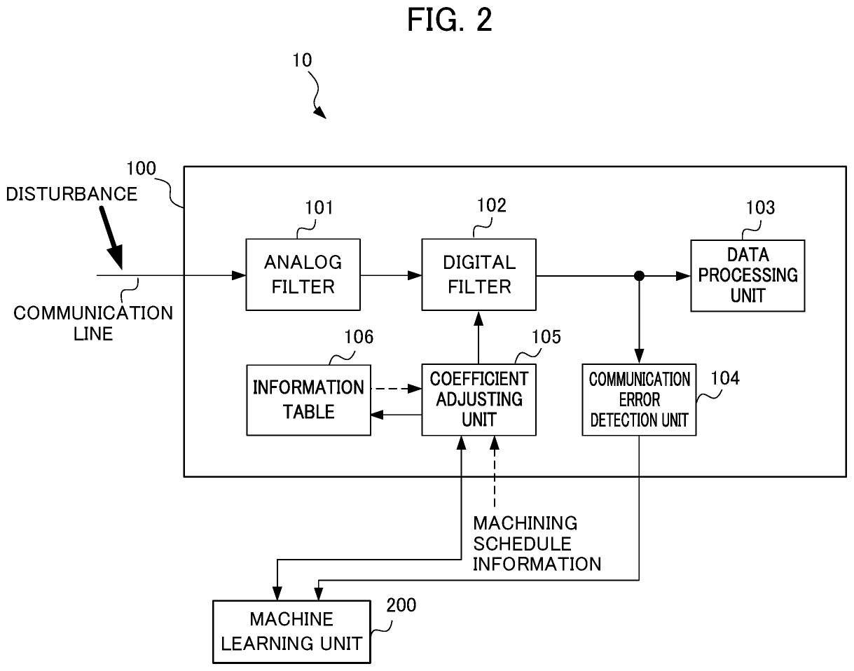

FIG. 1 is a block diagram showing the configuration after machine learning of a receiving device according to the first embodiment of the present disclosure. FIG. 2 is a block diagram showing a configuration during machine learning of the receiving device according to the first embodiment of the present disclosure. As shown in FIGS. 1 and 2, a receiving device 10 includes a receiving unit 100 and a machine learning unit 200. An apparatus provided with the receiving device 10 is not particularly limited. However, such an apparatus is, for example, a control device for controlling a machine tool, a robot, an industrial machine or the like, or a peripheral device or an I/O unit connected to the control device. The machine learning unit 200 may be included in the receiving unit 100. The control device may be a numerical control device. The receiving unit 100 includes an analog filter 101, a digital filter 102, a data processing unit 103, a communication error detecting unit 104, a coefficient adjusting unit 105, and an information table 106. In the information table, a combination of the machining type or the operation type and the correction information of the optimal coefficient of the digital filter 102 set by machine learning (the combination is a learned model in which the error rate is minimized) is recorded.

It should be noted that, in FIG. 1, the communication error detecting unit 104 and the machine learning unit 200 are denoted by broken lines, which indicate that the communication error detecting unit 104 and the machine learning unit 200 do not function after machine learning. Furthermore, the routes indicated by the broken lines in FIG. 1 indicate that the transmission and reception of information is not performed after machine learning. The machine learning unit 200 may be detached from the receiving device 10 after machine learning. The broken lines in FIG. 2 indicate paths through which transmission and reception of information is not performed during machine learning.

Hereinafter, each component of the receiving unit 100 will be further described. In the following description, unless otherwise stated, a case in which a device which causes disturbance is the machine tool will be described.

The analog filter 101 receives a signal via a communication line such as an industrial Ethernet or a communication line between I/O units. The digital filter 102 receives the output of the analog filter 101 and compensates the filter characteristics of the analog filter 101. The analog filter 101 and the digital filter 102 eliminate or attenuate disturbance applied to the communication line. It should be noted that, in a case in which the digital filter 102 is sufficient to remove disturbance, the analog filter 101 may not necessarily be provided. Since the filter characteristics of the analog filter 101 are determined by the components used, it is difficult to change the filter characteristics by adjusting parameters after mounting. It is possible to change the filter characteristics of the digital filter 102 by adjusting parameters.

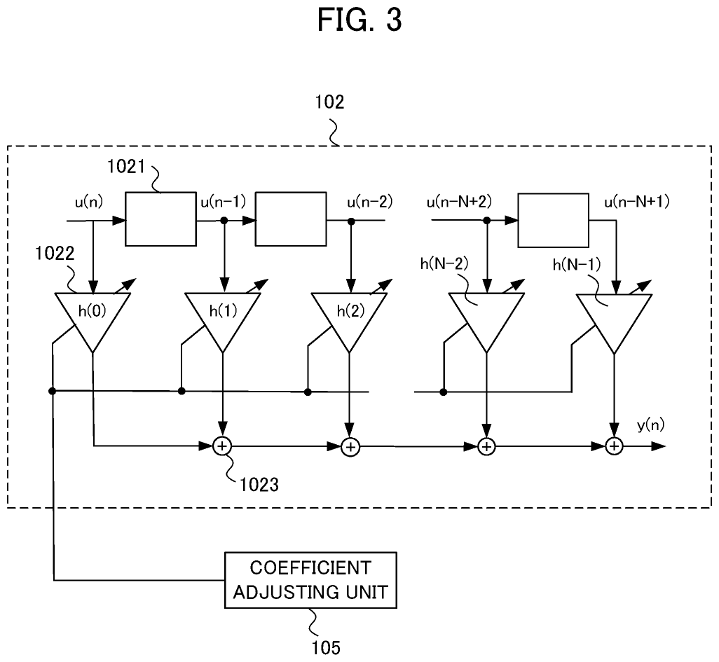

As the digital filter 102, for example, a FIR digital filter can be used. FIG. 3 is a block diagram showing a configuration example of the FIR digital filter. The FIR digital filter serving as the digital filter 102 includes a delay element 1021 of N-stages connected in series, (N+1) multipliers 1022, and an adder 1023 of N-stages connected in series. The number of tap stages of the FIR digital filter is fixed depending on the period of sampling. Each delay element 1021 delays a signal inputted by one sampling, and outputs it. Each multiplier 1022 performs multiplication of the signal that is to be outputted from the delay element 1021 and is subjected to sampling by a coefficient of the frequency to perform cutoff. An input signal is inputted to the multiplier 1022 of the first stage. By changing the weight of the tap coefficient of each multiplier 1022, the characteristics of the passband of the FIR filter is set. Each adder 1023 adds the multiplication results.

The output y(n) for the input u(n) of the FIR digital filter is expressed by the following Equation 1. h(i) in Equation 1 is a tap coefficient of the multiplier 1022.

$$y ( n ) = {\sum }_{i = 0}^{N - 1} h ( i ) u ( n - i ) \qquad [ Equation 1 ]$$

The data processing unit 103 performs data processing of an output outputted from the digital filter 102. The communication error detecting unit 104 performs error detection of an output signal outputted from the digital filter 102 using a CRC (Cyclic Redundancy Check) during machine learning, calculates the frequency (error rate) of errors in communication, and outputs the result to the machine learning unit 200. The CRC is a type of error detection code and is used for error detection in digital communication. The frequency of errors in communication (error rate) is information indicating the status of communication errors. However, for the information indicating the status of communication errors, parameters other than the frequency of errors in communication may be used. Furthermore, the error detection may be performed using an error detection code other than CRC. Errors detected by the communication error detecting unit 104 are caused, for example, by disturbance applied to signals inputted through the communication line. Examples of the disturbance includes, for example, disturbance by a machine tool, a motor for driving an industrial machine such as a conveyor or an industrial robot, an electromagnetic valve (solenoid valve) for driving a peripheral device, or an electromagnetic relay (relay) in the factory environment.

As shown in FIG. 2, during machine learning, the coefficient adjusting unit 105 adjusts the coefficient of the digital filter 102 based on information for correcting the coefficient of the digital filter 102 which is outputted from the machine learning unit 200. The coefficient adjusting unit 105 receives, for example, correction information of the optimal coefficient of the digital filter 102 for the machining type of the machine tool from the machine learning unit 200. The correction information is obtained by machine learning and serves as a condition of the surrounding environment of the communication line. Furthermore, the coefficient adjusting unit 105 records the combination of the machining type and the correction information of the optimal coefficient of the digital filter 102 in the information table 106. It should be noted that the coefficient adjusting unit 105 may record the corrected coefficient based on the correction information of the optimum coefficient in the information table 106. The coefficient adjusting unit 105 stores the coefficient of the current digital filter 102 and, when the coefficient is corrected, the coefficient adjusting unit 105 updates the coefficient.

As shown in FIG. 1, after machine learning, the coefficient adjusting unit 105 refers to a table recorded in the information table 106 based on machining schedule information to be inputted. This table shows a combination of the machining type and the correction information of the optimal coefficient of the digital filter 102 set by the machine learning. Furthermore, the coefficient adjusting unit 105 adjusts the tap coefficient h(i) (0≤i≤N−1) of the FIR digital filter serving as a coefficient of the digital filter 102. The machining schedule information is schedule information of machining of a machine tool and, when machining is performed according to a machining program, for example, it is information indicating which machining type is executed in which period. The machining schedule information corresponds to operation schedule information. In a case in which a device causing disturbance is a robot, an industrial machine, or a peripheral device, the operation schedule information is schedule information of each operation of the robot, the industrial machine, or the peripheral device, and is information indicating which operation type is executed in which period. It should be noted that the machining type indicates the type of machining of the machine tool, and the operation type indicates the type of operation of the robot, the industrial machine, or the peripheral device. The machining type and the operation type are operation information. The machining type and the operation type are included in the operation schedule information. The machining schedule information is transmitted from the PLC (Programmable Logic Controller) serving as a host device for controlling the operation of the machine tool to the coefficient adjusting unit 105. It should be noted that a device other than the PLC may be configured as a host device.

The information table 106 is a table in which the machining type and correction information of the optimal coefficient (for example, the tap coefficient of the FIR filter) of the digital filter 102 set by machine learning are associated with each other. Table 1 shows the corresponding relationship between the machining type of the machine tool M1 (machining P1 to P3) and the coefficient correction information for setting the digital filters F1 to F3 with different coefficients in a case in which the communication line is connected to the I/O unit and the machine tool, and the communication line is affected by the disturbance caused by the motor of the machine tool M1 depending on the machining type. Furthermore, Table 1 shows the corresponding relationship between machining P1 and P4 of the machine tools M1 and M2 and the coefficient correction information for setting the digital filter F1 in a case in which another machine tool M2 is disposed around the communication line and the communication line is affected by the disturbance caused by machining P4 of the machine tool M2 in addition to the disturbance caused by machining P1 of the machine tool M1. In Table 1, the correction information of the filter indicates the coefficient correction information for setting the digital filter corresponding to the machining type. It should be noted that the information recorded in the information table 106 is not limited to the coefficient correction information, and may be a corrected coefficient.

TABLE 1

| MACHINING | MACHINING | MACHINING | MACHINING | MACHINING | |
|---|---|---|---|---|---|
| TYPE | P1 | P2 | P3 | P1, P4 | . |
| FILTER | COEFFICIENT | COEFFICIENT | COEFFICIENT | COEFFICIENT | . |
| MODIFICATION | CORRECTION | CORRECTION | CORRECTION | CORRECTION | |
| INFORMATION | INFORMATION | INFORMATION | INFORMATION | INFORMATION | |
| | OF FILTER F1 | OF FILTER F2 | OF FILTER F3 | OF FILTER | |
| | | | | F1, F4 | |

The machine learning unit 200 grasps the machining or operation of a machine, a robot, or a device. The machine learning unit 200 performs machine learning (hereinafter, referred to as learning) of the coefficient of the digital filter 102 by using an error rate of the error caused by disturbance applied to a signal inputted to the communication line. The machine learning unit 200 is a machine learning device.

A specific example of the operation of the machine learning unit 200 regarding the disturbance applied to the signal inputted to the communication line will be described. (1) A control device having the receiving device 10 controls an amplifier for driving a motor of a machine tool based on a machining program and, when the receiving device 10 receives a signal from the I/O unit, disturbance by a motor may be applied to the communication line that connects the control device and the I/O unit due to the motor driven by an amplifier. When a machine tool is driven using a motor, the operation of the motor is associated with a machining program that controls the motor. Therefore, the machine learning unit 200 acquires a plurality of machining programs, and learns the coefficients of the digital filter 102 using an error rate for each machining type specified from a plurality of machining programs. Similarly, even in a case in which the receiving device 10 is provided to the I/O unit, the machine learning unit 200 can acquire a machining program from the control device and learn the coefficients of the digital filter 102 using an error rate for each machining type specified from the machining program.

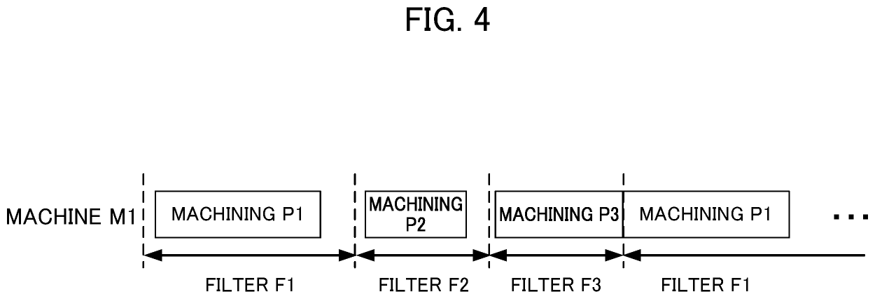

FIG. 4 is an explanatory diagram showing a state in which digital filters having different coefficients are set according to the machining type of a machine serving as a machine tool. A motor of the machine tool M1 (shown in FIG. 4 as machine M1) driven by a control device including the receiving device 10 is driven by a plurality of machining programs. Furthermore, the machine M1 performs the processes of the machining P1, machining P2, machining P3, and machining P1 in this order. Since machining P1, machining P2, and machining P3 are different machining processes, respectively, the disturbances caused by the motor are different from each other. The machine learning unit 200 adjusts the coefficients of the digital filter 102 for each type of machining (each of machining P1, machining P2, and machining P3) specified from the machining program to constitute the filters F1, F2, and F3 having different coefficients. This corresponding relationship is the same as the corresponding relationship shown in Table 1. The machine learning unit 200 sends correction information of the optimal coefficient of the digital filter 102 for the machining type calculated by learning. The coefficient adjusting unit 105 records the combination of the machining type and the correction information of the optimal coefficient of the digital filter 102 in the information table 106. Table 1 shows a table relating to machining P1 to P3 and correction information for the coefficients of the filters.

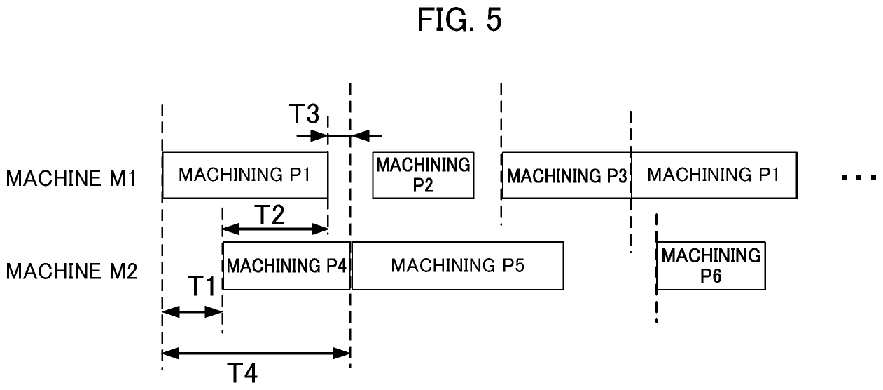

(2) In a case in which the control device of the machine tool having the receiving device 10 receives a signal from the I/O unit by the receiving device 10, and a motor of another machine tool placed in the vicinity of the communication line operates, disturbance caused by the motor of the other machine tool in addition to the disturbance described in (1) above may be applied to the communication line which connects the control device and the I/O unit. FIG. 5 is a diagram showing a machining type in a case in which two machines serving as machine tools are arranged side by side. A motor of the machine tool M1 (shown as machine M1 in FIG. 5) driven by a control device having the receiving device 10 is driven by a plurality of machining programs. Furthermore, the machine tool M1 performs machining P1, machining P2, machining P3, and machining P1 in this order. Since machining P1, machining P2, and machining P3 are different machining processes, respectively, the disturbances caused by the motor are different from each other. Furthermore, the motor of the machine tool M2 (shown as machine M2 in FIG. 5) is driven by a plurality of machining programs. Furthermore, the machine tool M2 performs the processes of the machining P4, machining P5, and machining P6 in this order. Since machining P4, machining P5, and machining P6 are different machining processes, respectively, the disturbances caused by the motor are different from each other. In this case, for example, the machining P1 and machining P3 include a period in which the motor of the machine tool M2 is not driven (e.g., the period T1 in FIG. 5 is a period in which the motor of the machine tool M2 is not driven). It suffices if the filter coefficients are set in the filters F1 and F3 described in (1) above.

However, for example, in the period T2, the machining P1 by the machine tool M1 and the machining P4 by the machine tool M2 are performed simultaneously. For this reason, the communication line may suffer from the disturbance caused by the motor drive in the machine tool M1 and the disturbance caused by the motor drive in the machine tool M2 at the same time. In this case, the machine learning unit 200 performs learning in the period T1 in which the motor of the machine tool M2 in the machining P1 is not driven. Furthermore, the machine learning unit 200 performs learning in the period T2 in which the machining P1 and machining P4 are simultaneously performed, and hence, the motors of the machine tools M1 and M2 are driven. In a case in which the coefficients of the learned digital filter 102 are the same or the amount of change in the coefficients is small, the machine learning unit 200 determines that there is no disturbance due to machining P4 or that the influence due to the disturbance is small. Then, in the period T2, the machine learning unit 200 can set the digital filter 102 to the filter 1 without changing the coefficient of the digital filter 102. Table 1 shows a table relating to the machining P1 and machining P4, and the correction information of the coefficients of the filter 1. It should be noted that, in a case in which a peripheral device having an electromagnetic valve (solenoid valve) or an electromagnetic relay (relay) is disposed in place of the machine tool M2, it is assumed that the influence of disturbance by the solenoid valve or the electromagnetic relay is large. In this case, in the period T2, the learning is performed on the peripheral device, and the coefficient of the digital filter 102 is set.

In addition, the digital filter 102 may be configured by two-stage digital filters connected in series. In such a case, the machine learning unit 200 performs learning in the period T1 in which the motor of the machine tool M2 in the machining P1 is not driven, and then sets the digital filter of the first stage in the filter F1. Furthermore, the machine learning unit 200 performs learning in a period T3 in which the motor of the machine tool M2 in the machining P4 is not driven, and sets the digital filter of the second stage in the filter F4. Thus, by configuring the digital filter 102 with two stages of the filter F1 and the filter F4, it is possible to set the optimal coefficient of the digital filter 102 without performing machine learning in the period T2.

In the above description, an example in which another machine tool is disposed in the vicinity of the communication line is described. However, the present invention is also applied to a case in which a peripheral device having an electromagnetic valve (solenoid valve) or an electromagnetic relay (relay) is disposed in the vicinity of a communication line, and disturbance due to the electromagnetic valve or the electromagnetic relay is applied to the communication line. There may be a case in which an industrial machine such as a conveyor driven by a motor or an industrial robot driven by a motor is disposed in the vicinity of the communication line.

The machine learning unit 200 uses information indicating the operation of the machine, the robot, and the device to grasp the machining or operation type, and learns the coefficients of the digital filter 102. The information is, for example, a machining program for driving a machine tool, an operation sequence program for driving an industrial machine or an industrial robot, or an operation sequence program for driving a peripheral device. It should be noted that, in a case in which a plurality of pieces among a machine tool, an industrial machine, an industrial robot, or peripheral devices are disposed in the vicinity of the signal line and, for example, as described in (2) above, when machining or operation is being performed in one machine tool M1 (for example, in a period of the period T1+the period T2), there may be a case in which machining or operation of another machine tool M2 is performed in the middle of the machining or operation (for example, in the period T2), and a new disturbance is applied to the signal line. In this case, in order to perform the learning in the overlapping period of the machining or the operation, information relating to the time at which the machining or the operation in the machine tool M2 starts may be necessary. In this case, the machine learning unit 200 may acquire information relating to the time at which the machining or operation starts from a control device that controls a machine tool, an industrial machine, an industrial robot, or peripheral devices. The machine learning unit 200 may also acquire information relating to either one or both the machining or operation type and the time at which the machining or operation starts, from a PLC (Programmable Logic Controller) serving as a host device that controls a plurality of operations of a machine tool, an industrial machine, an industrial robot, or peripheral devices.

### <Machine Learning Unit 200>

A method of adjusting the filter characteristics of the FIR filter based on an error rate by machine learning is described in Japanese Unexamined Patent Application, Publication No. H11-122311. In the present embodiment, a similar method can be employed with the machine learning unit 200. It should be noted that, in the following description, a case in which the machine learning unit 200 performs reinforcement learning will be described. However, the learning performed by the machine learning unit 200 is not particularly limited to reinforcement learning. The present invention is also applicable to, for example, a case in which supervised learning is performed. The details of the reinforcement learning are described in, for example, Japanese Unexamined Patent Application, Publication Nos. 2018-152012 and 2019-021024. Therefore, in the following description, the machine learning unit 200 applied to the present embodiment will be briefly described.

Prior to the description of each functional block included in the machine learning unit 200, a basic mechanism of reinforcement learning will be described first. An agent, which corresponds to the machine learning unit 200 in the present embodiment, observes the state of the environment and selects a certain action. Then, the environment changes based on the action. As the environment changes, something is rewarded, and the agent learns to make better choices of action (decisions). Supervised learning presents a complete correct answer. In contrast, rewards in reinforcement learning are often fragmentary values based on changes in some parts of the environment. For this reason, the agent learns to choose an action to maximize the total reward over the future.

As described above, by learning actions in the reinforcement learning, it is a method of learning an appropriate action based on the interactions in which the action affects the environment, i.e., a method of learning how to maximize future rewards. This means that, in the present embodiment, for example, it is possible to acquire an action that affects the future, i.e., to select action information for compensating for the inter-axis interference in the servo control unit relating to the axis subject to interference.

Herein, any learning method can be used as the reinforcement learning. The following explanation provides a description of Q learning, which is a method of learning the value Q(S, A) of selecting the action A, is used under the state S of a certain environment. The purpose of the Q learning is to select the action A having the highest value Q(S, A) as an optimal action from among the possible actions A in a certain state S.

However, at the time of starting the Q learning first, the correct value of the value Q(S, A) is completely unknown for the combination of the state S and the action A. Then, the agent selects various actions A under a certain state S, and learns the correct value Q(S, A) by selecting a better action based on the reward given to the action A at that time.

In addition, the Q learning aims to maximize the total reward to be obtained over the future, so that Q(S, A)=E[Σ(γ^{t})rₜ] is finally obtained. In this equation, E[ ] is the expected value, t is the time, γ is a parameter called the discount rate, rₜ is the reward at time t, and Σ is the total at time t. The expected value in this equation is an expected value when a state changes according to the optimal action. However, since it is unclear what the optimal action is in the process of the Q learning, various actions are performed to perform reinforcement learning while searching. An update expression of such a value Q(S, A) can be expressed by, for example, the following Equation 2.

$$Q ( {S}_{t + 1} , {A}_{t + 1} ) ← Q ( {S}_{t} , {A}_{t} ) + α ( {r}_{t + 1} + γ {max}_{A} Q ( {S}_{t + 1} , A ) - Q ( {S}_{t} , {A}_{t} ) ) \qquad [ Equation 2 ]$$

In Equation 2 above, Sₜ represents the state of the environment at time t, and Aₜ represents the action at time t. According to the action Aₜ, the state changes to Sₜ₊₁. rₜ₊₁ represents the reward obtained by the change in state. Furthermore, a term to which “max” is attached is obtained by multiplying the Q value obtained when the action A with the highest Q value known at that time is selected under the state Sₜ₊₁ by γ. Here, γ is a parameter of 0<γ≤1, and is called a discount rate. Furthermore, α is a learning coefficient in the range of 0<α≤1.

Equation 3 described above represents a method of updating the value Q(Sₜ, Aₜ) of the action Aₜ in the state Sₜ based on the return reward rₜ₊₁ as a result of the trial Aₜ. This updating equation shows that if the value maxₐ Q(Sₜ₊₁, A) of the best action in the next state Sₜ₊₁ by the action Aₜ is larger than the value Q(Sₜ, Aₜ) of the action Aₜ in the state Sₜ, then Q(Sₜ, Aₜ) is increased, and conversely, if it is smaller, Q(Sₜ, Aₜ) is decreased. In other words, the value of one action in one condition is brought closer to the value of the best action in the next state. However, although the difference depends on the way the discount rate γ and the reward rₜ₊₁ are used, basically the value of the best action in one state propagates to the value of an action in the immediately preceding state. The machine learning unit 200 performs the Q learning described above.

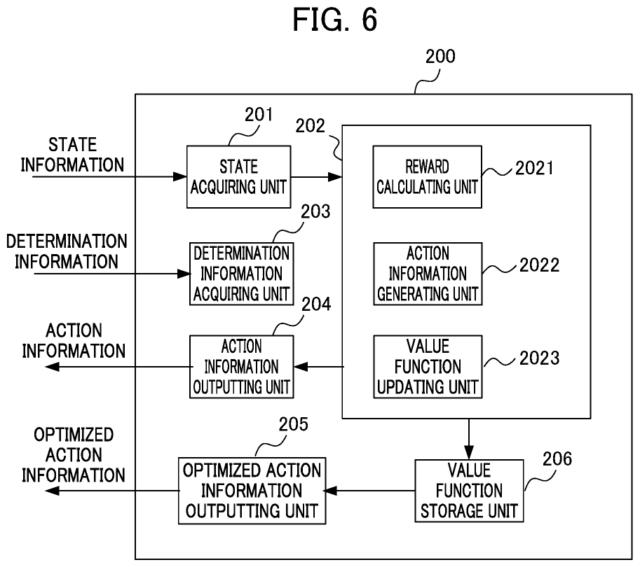

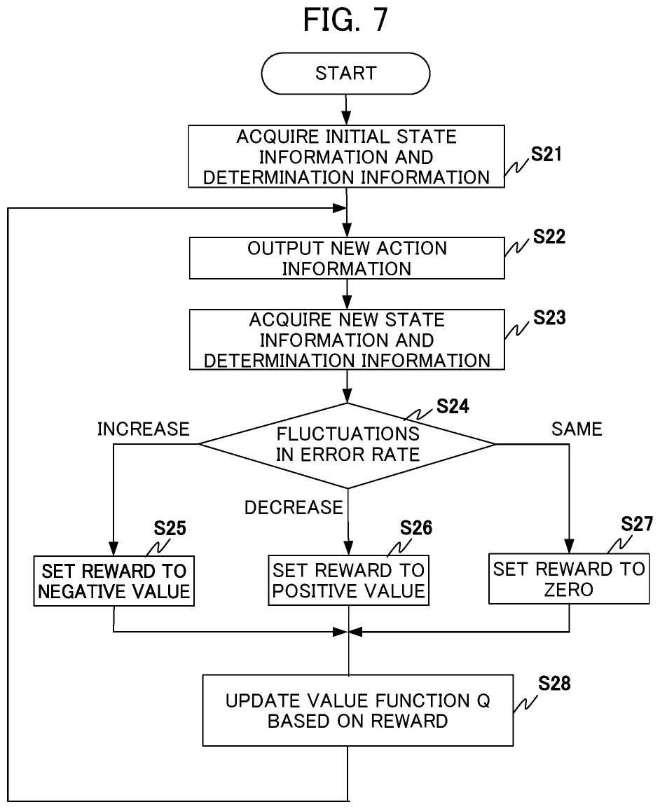

FIG. 6 is a block diagram showing a configuration of a machine learning unit 200 of the present disclosure. FIG. 7 is a flowchart for explaining the operation of the machine learning unit 200 according to the present disclosure. As shown in FIG. 6, in order to perform reinforcement learning, the machine learning unit 200 includes a state acquiring unit 201, a learning unit 202, a determination information acquiring unit 203, an action information outputting unit 204, an optimized action information outputting unit 205, and a value function storage unit 206. Hereinafter, the operation of the machine learning unit 200 will be described with reference to FIGS. 6 and 7. In the following description, an example will be described in which the machine learning unit 200 executes the operation in (1) described above. As shown in FIG. 6, in Step S21, the state acquiring unit 201 acquires the machining type from the control device of the machine tool M1 (corresponding to the type of machining program), for example, the machining P1, as the state information of the first state S, and acquires the tap coefficient h(i) (0≤i≤N−1) of the FIR filter as a coefficient of the digital filter 102 from the coefficient adjusting unit 105. The determination information acquiring unit 203 acquires an error rate as determination information from the communication error detecting unit 104 of the receiving device 10. In Step S22, the action information generating unit 2022 of the learning unit 202 generates information for correcting the tap coefficient h(i) so as to minutely vary (minute increase or minute decrease) the filter characteristics of the FIR filter serving as the digital filter 102. Then, in Step S22, the action information outputting unit 204 sends information for correcting the tap coefficient h(i) to the coefficient adjusting unit 105 as the action information. It should be noted that the coefficient adjusting unit 105 that has received the action information corrects the tap coefficient h(i) (0≤i≤N−1) of the FIR filter related to the current state S based on the received action information. The machine tool M1 performs machining P1 according to the state S′ in which the tap coefficient h(i) (0≤i≤N−1) has been corrected. In Step S23, the state acquiring unit 201 acquires the machining P1, which is the machining type, in the new state S′. Then, the state acquiring unit 201 acquires the tap coefficient h(i) (0≤i≤N−1) of the FIR filter serving as the coefficient of the digital filter 102 from the coefficient adjusting unit 105. Furthermore, the determination information acquiring unit 203 acquires the error rate in the new state S′ as the determination information from the communication error detection unit 104 of the receiving device 10.

In Step S24, the reward calculating unit 2021 compares the error rate in the state S′ with the error rate in the state S to determine a variation in the error rate. When the error rate in the state S′ increases more than the error rate in the state S, the reward calculating unit 2021 sets the reward to a negative value in Step S25. On the other hand, when the error rate in the state S′ decreases lower than the error rate in the state S, the reward calculating unit 2021 sets the reward to a positive value in Step S26. When the error rate in the state S′ is the same as the error rate in the state S, in Step S27, the reward calculating unit 2021 sets the reward to zero. It should be noted that the negative value and the positive value of the reward may be weighted.

When any one of Steps S25, S26, and S27 ends, in Step S28, the value function updating unit 2023 updates the value function Q stored in the value function storage unit 206 based on the value of the reward calculated in any one of the steps. Then, the processing returns to Step S22 again, and the above-described processing is repeated. As a result, the value function Q converges to an appropriate value.

The optimized action information outputting unit 205 acquires the value function Q stored in the value function storage unit 206. The value function Q is updated by the value function updating unit 2023 performing the Q learning as described above. The optimized action information outputting unit 205 generates the optimized action information based on the value function Q, and outputs the generated optimized action information (correction information of the tap coefficient h(i) (0≤i≤N−1)) and information indicating machining P1 serving as the machining type, to the coefficient adjusting unit 105 of the receiving unit 100. It should be noted that the coefficient adjusting unit 105 that has received the optimized action information stores the correction information of the tap coefficient h(i) (0≤i≤N−1) of the FIR filter in the information table 106 in association with the machining P1 based on the received optimized action information and the information indicating the machining P1 serving as the machining type. By performing the above learning on the machining P2 and P3, it becomes possible to create a table relating to the machining P1 to P3 and the correction information of the coefficients of the filters in Table 1.

In the operation of the machine learning unit 200 described above, the machine tool is adopted as an example, and as the state information, the machining type corresponding to the type of machining program of the machine tool is adopted as an example. However, when a robot, an industrial machine, or the like is used instead of the machine tool, the type of the sequence program can be used as the state information.

The functional blocks included in the receiving unit 100 of the receiving device 10 and the machine learning unit 200 have been described above. To realize these functional blocks, the receiving device 10 includes an arithmetic processing unit such as a CPU (Central Processing Unit). Furthermore, the receiving device 10 includes an auxiliary storage device such as a HDD (Hard Disk Drive) that stores various control programs such as application software and OS (Operating System), and further includes a main storage device such as RAM (Random Access Memory) for storing data temporarily required for the arithmetic processing unit to execute the programs.

Then, in the receiving device 10, the arithmetic processing unit reads the application software and the OS from the auxiliary storage device, and performs arithmetic processing based on the application software and the OS while expanding the read application software and the OS in the main storage device. Furthermore, based on the calculation result, various kinds of hardware provided in each device is controlled. As a result, the functional blocks of the present embodiment are realized. In other words, the present embodiment can be realized by the cooperation of hardware and software.

The machine learning unit 200 has a large computational complexity associated with machine learning. For this reason, for example, a GPU (Graphics Processing Units) is built into a personal computer, and the GPU may be configured to be used for arithmetic processing associated with machine learning using a technique called GPGPU (General-Purpose computing on Graphics Processing Units). It is favorable in that this configuration enables high-speed processing. Further, in order to perform faster processing, a computer cluster may be constructed using a plurality of computers equipped with such a GPU, and parallel processing may be performed by a plurality of computers included in the computer cluster.

Each component included in the receiving device 10 can be realized by hardware, software, or a combination thereof. Furthermore, the servo control method performed by the cooperation of the respective components included in the above-described motor control device can also be realized by hardware, software, or a combination thereof. Herein, being realized by software indicates being realized by a computer reading and executing a program.

Programs can be stored using various types of non-transient computer readable media (non-transitory computer readable medium) and supplied to a computer. The non-transitory computer readable media include various types of tangible storage media. Examples of non-transient computer-readable media include magnetic recording media (e.g., hard disk drives), magnetic-optical recording media (e.g., magnetic-optical disks), CD-ROM (Read Only Memory), CD-R, CD-R/W, and semiconductor memory (e.g., mask ROM, PROM (Programmable ROM), EPROM (Erasable PROM, flash ROM, and RAM (random access memory)).

The embodiments described above are preferred embodiments of the present invention; however, they are not intended to limit the scope of the present invention only to the above embodiments. The above-described embodiments can be implemented in a form in which various changes are made without departing from the gist of the present invention.

The receiving device has the following configuration in addition to the configuration shown in FIG. 1.

<Modification Example in which Machine Learning Unit is Provided Outside Receiving Device>

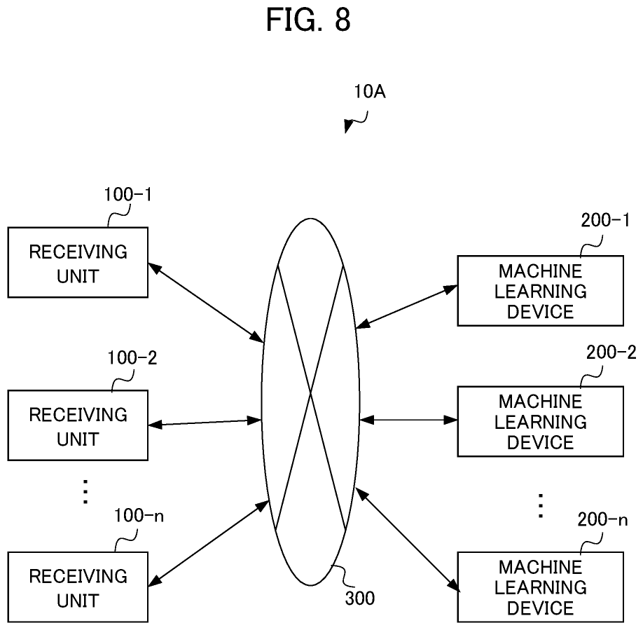

In the present modification example, since the machine learning unit is provided independently of the receiving device, it is called a machine learning device. FIG. 8 is a block diagram showing another configuration example of a receiving device including a receiving unit and a machine learning device. The receiving device 10A shown in FIG. 8 includes n-number (n is a natural number of 2 or more) of receiving units 100-1 to 100-n, n-number of machine learning devices 200-1 to 200-n, and a network 300 connecting the receiving units 100-1 to 100-n and the n-number of machine learning devices 200-1 to 200-n. The n-number (n is a natural number of 2 or more) of receiving units 100-1 to 100-n are included in a machine tool, a robot, a control device for controlling an industrial machine or the like, or a peripheral device or I/O unit connected to the control device or the like. The receiving units 100-1 to 100-n have the same configuration as the receiving unit 100. The machine learning devices 200-1 to 200-n have the same configuration as the machine learning unit 200 shown in FIG. 6.

Herein, the receiving unit 100-1 and the machine learning device 200-1 are connected in a one-to-one group so as to be able to communicate with each other. The receiving units 100-2 to 100-n and the machine learning devices 200-2 to 200-n are also connected in the same manner as the receiving unit 100-1 and the machine learning device 200-1. In FIG. 8, n-number of groups of receiving units 100-1 to 100-n and machine learning devices 200-1 to 200-n are connected via the network 300. However, for n-number of groups of the receiving units 100-1 to 100-n and the machine learning devices 200-1 to 200-n, each group of the receiving units and the machine learning devices may be directly connected via a connection interface. The n-number of groups of these receiving units 100-1 to 100-n and the machine learning device 200-1 to 200-n may be installed in a plurality of groups, for example, in the same factory, or may be installed in different factories, respectively.

It should be noted that the network 300 is, for example, a LAN (Local Area Network) constructed in the factory, the Internet, a public telephone network, or a combination thereof. There is no particular limitation on the communication through the network 300 in terms of a specific communication system or in terms of whether the communication is established as a wired connection or wireless connection.

### <Degree of Freedom of System Configuration>

In the above-described embodiment, the receiving units 100-1 to 100-n and the machine learning devices 200-1 to 200-n are respectively connected with each other in one-to-one groups to communicate with each other. However, for example, one machine learning device may be connected to a plurality of receiving units via the network 300 so as to be able to communicate with each other, and the machine learning of the digital filter of each receiving unit may be performed. In this case, each function of one machine learning device may be distributed to a plurality of servers as appropriate to establish a distributed processing system. In addition, each function of one machine learning device may be realized by using a virtual server function or the like on a cloud.

A machine learning device, a control system, and a machine learning method according to the present disclosure can be adopted in various embodiments having the following configurations including the above-described embodiments. (1) The first aspect of the present disclosure is a receiving device 10 including: a digital filter 102 that eliminates or attenuates a disturbance included in a signal received through a communication line; a coefficient adjusting unit 105 that adjusts a coefficient of the digital filter 102 based on operation schedule information of a device causing the disturbance in the communication line; and an information table 106 that records a combination of operation information included in the operation schedule information and a coefficient of the digital filter 102 corresponding to the operation information or correction information of the coefficient, in which the coefficient adjusting unit 105 calculates the coefficient of the digital filter 102 or the correction information of the coefficient from the information table 106 based on the operation information included in the operation schedule information, and adjusts the coefficient of the digital filter 102. According to the receiving device of the present disclosure, it is possible to adjust digital filters suited to disturbances occurring in the surroundings based on the operation schedule information of the device causing the disturbance.

(2) The receiving device 10 according to (1) above, in which the device is a machine tool, a robot, an industrial machine, or a peripheral device, and the operation information is information relating to a type of machining of the machine tool, or a type of operation of the robot, the industrial machine, or the peripheral device.

(3) The receiving device 10 according to (2) above, in which the operation information is calculated based on a machining program or an operation sequence program.

The fourth aspect of the present disclosure is a machine learning device 200 that performs machine learning for an optimal coefficient of a digital filter 102 relative to a receiving device which includes: the digital filter 102 that eliminates or attenuates a disturbance included in a signal received through a communication line; a coefficient adjusting unit 105 that adjusts a coefficient of the digital filter 102 based on operation schedule information of a device causing the disturbance in the communication line; an information table 106 that records a combination of operation information included in the operation schedule information and a coefficient of the digital filter 102 corresponding to the operation information or correction information of the coefficient; and a communication error detecting unit 104 that detects a communication error based on an output of the digital filter 102, includes: a state acquiring unit 201 that acquires operation information of the device causing the disturbance in the communication line and the coefficient of the digital filter, as state information; an action information outputting unit 204 that outputs action information including adjustment information of the coefficient included in the state information to the coefficient adjusting unit 105; a determination information acquiring unit 203 that acquires determination information indicating a status of a communication error from the communication error detecting unit 104; and a reward calculating unit 2021 that gives a reward relative to a variation in the communication error based on the determination information, in which the machine learning device performs machine learning for an optimal coefficient of the digital filter 102 so that the communication error decreases, using a value of the reward. According to the machine learning device of the present disclosure, it is possible to learn the coefficients of digital filters suited to disturbances occurring in the surroundings based on the operation schedule information of the device causing the disturbance.

(5) The machine learning device 200 according to (4) above, further including a value function updating unit 2023 that updates a value function based on the value of the reward and the state information.

(6) The machine learning device 200 according to (5) above, further including an optimized action information outputting unit 205 that outputs adjustment information of the coefficient to the coefficient adjusting unit 105 based on a value function updated by the value function updating unit 2023.

(7) The machine learning device 200 according to any one of (4) to (6) above, in which the determination information indicating a status of a communication error is an error frequency in communication.

(8) The machine learning device 200 according to any one of (4) to (7) above, in which the device is a machine tool, a robot, an industrial machine, or a peripheral device, and the operation information is information relating to a type of machining of the machine tool, or a type of operation of the robot, the industrial machine, or the peripheral device.

(9) The machine learning device 200 according to any one of (4) to (8) above, in which the operation information is calculated based on a machining program or an operation sequence program.

(10) The third aspect of the present disclosure is a receiving device 10 including: the machine learning device 200 according to any one of (4) to (9) above, and a receiving device including: a digital filter 102 that eliminates or attenuates a disturbance included in a signal received through a communication line; a coefficient adjusting unit 105 that adjusts a coefficient of the digital filter 102; a communication error detecting unit 104 that detects a communication error based on an output of the digital filter 102; and an information table 106 that indicates operation information of a device causing the disturbance in the communication line and the coefficient that is optimized or adjustment information of the coefficient outputted from the machine learning device 200. According to the receiving device of the present disclosure, it is possible to adjust digital filters suited to disturbances occurring in the surroundings based on the operation schedule information of the device causing the disturbance.

(11) The fourth aspect of the present disclosure is a machine learning method of a machine learning device 200 that performs machine learning for an optimal coefficient of a digital filter 102 relative to a receiving device which includes: a digital filter 102 that eliminates or attenuates a disturbance included in a signal received through a communication line; a coefficient adjusting unit 105 that adjusts a coefficient of the digital filter 102 based on operation schedule information of a device causing the disturbance in the communication line; an information table 106 that records a combination of operation information included in the operation schedule information and a coefficient of the digital filter corresponding to the operation information or correction information of the coefficient, and a communication error detecting unit 104 that detects a communication error based on an output of the digital filter 102, the machine learning method comprising the steps of: acquiring operation information of the device causing the disturbance in the communication line and the coefficient of the digital filter 102 as state information; outputting action information including adjustment information of the coefficient included in the state information to the coefficient adjusting unit 105; acquiring determination information indicating a status of a communication error from the communication error detecting unit 104; giving a reward in relation to a variation in the communication error based on the determination information; and performing machine learning for an optimal coefficient of the digital filter 102 so that the communication error decreases, using a value of the reward. According to the machine learning device of the present disclosure, it is possible to learn the coefficients of digital filters suited to disturbances occurring in the surroundings based on the operation schedule information of the device causing the disturbance.

### EXPLANATION OF REFERENCE NUMERALS

10, 10a receiving device
100 receiving unit
200 machine learning unit
101 analog filter
102 digital filter
103 data processing unit
104 communication error detecting unit
105 coefficient adjusting unit
201 state acquiring unit
202 learning unit
203 determination information acquiring unit
204 action information outputting unit
205 optimized action information outputting unit
206 value function storage unit
200-1 to 200-n machine learning device
300 network

What is claimed is:

1. A receiving device comprising:
a digital filter that eliminates or attenuates a disturbance included in a signal received through a communication line;
a coefficient adjusting unit that adjusts a coefficient of the digital filter based on operation schedule information of a device causing the disturbance in the communication line; and
an information table that records a combination of operation information included in the operation schedule information and a coefficient of the digital filter corresponding to the operation information or correction information of the coefficient,
wherein the coefficient adjusting unit calculates the coefficient of the digital filter or the correction information of the coefficient from the information table based on the operation information included in the operation schedule information, and adjusts the coefficient of the digital filter.

2. The receiving device according to claim 1, wherein the device is a machine tool, a robot, an industrial machine, or a peripheral device, and the operation information is information relating to a type of machining of the machine tool, or a type of operation of the robot, the industrial machine, or the peripheral device.

3. The receiving device according to claim 2, wherein the operation information is calculated based on a machining program or an operation sequence program.

4. A machine learning device that performs machine learning for an optimal coefficient of a digital filter relative to a receiving device which includes: the digital filter that eliminates or attenuates a disturbance included in a signal received through a communication line; a coefficient adjusting unit that adjusts a coefficient of the digital filter based on operation schedule information of a device causing the disturbance in the communication line; an information table that records a combination of operation information included in the operation schedule information and a coefficient of the digital filter corresponding to the operation information or correction information of the coefficient; and a communication error detecting unit that detects a communication error based on an output of the digital filter, the machine learning device comprising:
a state acquiring unit that acquires operation information of the device causing the disturbance in the communication line and the coefficient of the digital filter, as state information;
an action information outputting unit that outputs action information including adjustment information of the coefficient included in the state information to the coefficient adjusting unit;
a determination information acquiring unit that acquires determination information indicating a status of a communication error from the communication error detecting unit; and
a reward calculating unit that gives a reward relative to a variation in the communication error based on the determination information,
wherein the machine learning device performs machine learning for an optimal coefficient of the digital filter so that the communication error decreases, using a value of the reward.

5. The machine learning device according to claim 4, further comprising a value function updating unit that updates a value function based on the value of the reward and the state information.

6. The machine learning device according to claim 5, further comprising an optimized action information outputting unit that outputs adjustment information of the coefficient to the coefficient adjusting unit based on a value function updated by the value function updating unit.

7. The machine learning device according to claim 4, wherein the determination information indicating a status of a communication error is an error frequency in communication.

8. The machine learning device according to claim 4, wherein the device is a machine tool, a robot, an industrial machine, or a peripheral device, and the operation information is information relating to a type of machining of the machine tool, or a type of operation of the robot, the industrial machine, or the peripheral device.

9. The machine learning device according to claim 4, wherein the operation information is calculated based on a machining program or an operation sequence program.

10. A receiving device comprising:
the machine learning device according to claim 4, and
a receiving device including: a digital filter that eliminates or attenuates a disturbance included in a signal received through a communication line; a coefficient adjusting unit that adjusts a coefficient of the digital filter; a communication error detecting unit that detects a communication error based on an output of the digital filter; and an information table that indicates operation information of a device causing the disturbance in the communication line and the coefficient that is optimized or adjustment information of the coefficient outputted from the machine learning device.

11. A machine learning method of a machine learning device that performs machine learning for an optimal coefficient of a digital filter relative to a receiving device which includes: a digital filter that eliminates or attenuates a disturbance included in a signal received through a communication line; a coefficient adjusting unit that adjusts a coefficient of the digital filter based on operation schedule information of a device causing the disturbance in the communication line; an information table that records a combination of operation information included in the operation schedule information and a coefficient of the digital filter corresponding to the operation information or correction information of the coefficient, and a communication error detecting unit that detects a communication error based on an output of the digital filter, the machine learning method comprising the steps of:
acquiring operation information of the device causing the disturbance in the communication line and the coefficient of the digital filter as state information;
outputting action information including adjustment information of the coefficient included in the state information to the coefficient adjusting unit;
acquiring determination information indicating a status of a communication error from the communication error detecting unit;
giving a reward in relation to a variation in the communication error based on the determination information; and
performing machine learning for an optimal coefficient of the digital filter so that the communication error decreases, using a value of the reward.
